(19) United States
(12) Patent Application Publication
(10) Pub. No.: US 2017/0350834 A1
(43) Pub. Date: Dec. 7, 2017

(54) APPARATUS AND METHOD FOR DETECTING CONCEALED EXPLOSIVES

(71) Applicant: ONE RESONANCE SENSORS, LLC, San Diego, CA (US)

(72) Inventors: Pablo PRADO, San Diego, CA (US); James CHEPIN, San Diego, CA (US); Shouquin HUO, San Diego, CA (US); Robert LOWN, San Diego, CA (US); Kevin DERBY, Carlsbad, CA (US); Greg HOLIFIELD, Eustis, FL (US); Jonathan ZINN, San Diego, CA (US)

(73) Assignee: ONE RESONANCE SENSORS, LLC, San Diego, CA (US)

(21) Appl. No.: 15/529,068

(22) PCT Filed: Sep. 4, 2015
(86) PCT No.: PCT/US2015/048720

§ 371 Date: May 23, 2017

Related U.S. Application Data
(60) Provisional application No. 62/048,710, filed on Sep. 10, 2014.

(51) Int. Cl. G01N 24/08; G01R 33/44; G01V 3/12; G01V 3/14

(52) U.S. Cl. CPC G01N 24/084; G01V 3/14; G01R 33/441; G01V 3/12

(57) ABSTRACT

Explosives concealed within electronic devices, such as smartphones and tablet PCs, are detected using NQR spectroscopy. For example, a suspect electronic device can be placed inside a NQR scanner and be subject to interrogation electromagnetic radiation at varying frequencies. The electronic device is exposed to interrogation electromagnetic radiation at frequencies that correspond to chemical components of various explosives. In the event that an explosive chemical component is present inside the electronic device, irradiating the electronic device with interrogation electromagnetic radiation at the specific NQR frequency of that explosive chemical component will cause the explosive chemical component to emit feedback electromagnetic radiation at that frequency. Consequently, the NQR scanner can measure the feedback electromagnetic radiation and determine that the frequency of the feedback electromagnetic radiation indicates the presence of the explosive chemical component inside the electronic device.

### BACKGROUND

### Field of the Invention

The present invention is generally related to the detection of explosives and is more specifically related to the detection of concealed explosives in electronic devices using nuclear quadrupole resonance (NQR) spectroscopy.

### Related Art

Hidden explosives pose a significant and well-documented threat to public safety. Mass transit systems, particularly commercial airliners, have been a perpetual target for acts of terrorism. Over the last three decades, the extent of passenger and luggage screening has drastically increased in response to atrocities like the bombing of Pan Am Flight 103 and the September 11 attacks. But while some of the more recent attempts to smuggle explosives onboard aircrafts have been crude, security experts anticipate that the next iteration of improvised explosive devices to emerge will be much more sophisticated and effective as a result.

In particular, security experts are warning of efforts to convert common models of portable consumer electronic devices (e.g., smartphones, tablet PCs) into stealth explosive contraptions. In this manner, explosives materials are cleverly disguised to successfully evade conventional detection methods. X-Rays, for example, do not provide sufficient spatial resolution to enable a proper inspection of the internal composition of electronic devices. In particular, explosive materials that have been arranged in a sheet or planar configuration inside, for example, an iPhone® or an iPad® will generally appear innocuous in an X-Ray scan. Explosive trace detectors (ETDs), meanwhile, rely on the presence of particulates. As such, cleaning the exterior surface of an electronic device after modifying the electronic device to include explosive materials will effectively frustrate the ability of an ETD to accurately identify the electronic device as a threat. Finally, canine detection units are expensive to maintain and operate. In practice, bomb sniffing dogs require frequent breaks and can exacerbate congestion at crowded security checkpoints. In addition, it is possible for concealed explosive materials to be hermetically sealed within a modified electronic device, which would render common scent or vapor detection methods (e.g., bomb sniffing dogs, explosive vapor detector) virtually useless.

### SUMMARY

To effectively and efficiently detect concealed explosives, various embodiments of the apparatus and method described herein are directed toward the use of nuclear quadrupole resonance (NQR) spectroscopy to detect the presence of one or more types of solid explosive compounds, substances, or materials. In various embodiments, NQR spectroscopy is used to detect explosives that have been deliberately embedded, camouflaged, or otherwise concealed within an electronic device. In various embodiments, NQR spectroscopy is used to detect various types of solid explosives (e.g., plastic explosives) concealed within personal or portable electronic devices, including but not limited to smartphones, tablet PCs, laptops, and headsets.

NQR is a chemical analysis technique that exploits the electric quadrupole moment possessed by certain atomic nuclei (e.g., ¹⁴N, ¹⁷O, ³⁵Cl, and ⁶³Cu). An electric quadrupole moment arises from the presence of two adjacent electric dipoles (i.e., opposite charges separated by a short distance) in an atomic nucleus. Otherwise stated, an electric quadrupole moment is caused by an asymmetry in the distribution of the positive electric charge within the nucleus, which is typically the case for any atomic nucleus described as either a prolate (i.e., “stretched”) or oblate (i.e., “squashed”) spheroid. The interaction between the intrinsic electric quadrupole moment and an electric field gradient (EFG) within the nucleus generates distinct energy states. As such, the primary goal of NQR spectroscopy is to determine the resonant or NQR frequency at which the transition between these distinct energy states occur and then relate this property to a specific material, substance, or compound. Since the EFG surrounding a nucleus in a given substance is determined primarily by the valence electrons engaged in the formation of chemical bonds with adjacent nuclei, different substances will exhibit distinct resonant or NQR frequencies. The NQR frequency of a substance depends on both the nature of each atom comprising the substance and on the overall chemical environment (i.e., the other atoms in the substance). This renders NQR spectroscopy especially sensitive to the chemistry or composition of each substance. When a substance is irradiated or interrogated with radio frequency (RF) electromagnetic radiation, energy will be absorbed by each nucleus within the substance when the frequency of the interrogation electromagnetic radiation coincides with the specific NQR frequency for that substance. The absorption of energy at the specific NQR frequency for the substance causes a transition to a higher energy state followed by an emission of energy (i.e., feedback electromagnetic radiation) during a subsequent return to a lower energy state. This emission of energy is at the same frequency as the NQR frequency specific to that substance. As such, the NQR frequency of the feedback electromagnetic radiation emitted by a substance can act as a chemical signature for that substance. With respect to explosives, the NQR frequency of one or more chemical components of an explosive substance, material, or compound can be used to identify the presence of the explosive regardless of efforts to physically conceal the explosives, such as within an electronic device.

In the various embodiments described herein, explosives concealed within electronic devices are detected using a NQR scanner. In various embodiments, the NQR scanner is configured to detect one or more different types of solid explosive materials, substances, or compounds. In fact, in various embodiments, the NQR scanner is capable of detecting any desired, required, or appropriate number of different explosive materials, substances, or compounds, including but not limited to a variety of plastic explosives. In some exemplary embodiments, the NQR scanner is a tabletop device that includes a detection cavity. In various embodiments, the detection cavity comprises an opening, a drawer, a conveyor system, or any other appropriate receptacle, medium, and/or mechanism to hold, enclose, or otherwise contain a target object such as an electronic device during the NQR scanning process. Electronic devices such as smartphones, tablet PCs, and laptops generally include a number of conductive surfaces. Exposing a conductive surface to interrogation electromagnetic radiation from an undesirable or unsuitable angle (e.g., substantially orthogonal to the conductive surface) tends to induce an electric current across the conductive surface. An electric current across any of the conductive surfaces in an electronic device could generate false signals that mask the feedback electromagnetic radiation from explosive materials, substances, or compounds that may be hidden within the electronic device. Thus, in certain exemplary embodiments, the detection cavity is further configured to orient the conductive surfaces of the electronic device at a desirable or suitable angle with respect to the direction of the interrogation electromagnetic radiation.

In various embodiments, once inserted inside the detection cavity, the target object is subject to a sequence of specifically timed interrogation electromagnetic radiation. That is, in various embodiments, the NQR scanner tests the target object for the presence of various chemical components of explosive materials, substances, or compounds by irradiating the electronic device with certain frequencies of interrogation electromagnetic radiation and measuring the frequencies of the feedback electromagnetic radiation that is emitted in response. For example, in some embodiments, the NQR scanner is configured to detect the NQR frequency that uniquely identifies the primary explosive compound(s) found in certain plastic explosives.

Furthermore, in various embodiments, the NQR scanner is configured to detect interference and noise signals, including but not limited to signals from intentional jamming, the environment, and the target object itself. In some embodiments where the target object is an electronic device such as a smartphone or a tablet PC, powering on the device can generate unwanted noise signals that mask feedback electromagnetic radiation from explosive materials, substances, or compounds potentially hidden within the electronic device. In certain exemplary embodiments, the NQR scanner is configured to mitigate the effects of various interference and noise signals. As one example, in certain exemplary embodiments, the NQR scanner includes one or more shielding mechanisms to block, suppress, or otherwise minimize interference and noise signals from the surrounding environment. In various embodiments, the NQR scanner can be additionally or alternately configured to report unusually high levels of interference or noise signals. Additionally, in some exemplary embodiments, the NQR scanner provides a simple user interface. For example, in some embodiments, the NQR scanner is configured to provide a visual and/or audio alarm to indicate when the scanner encounters one or more different types of explosive materials.

Other features and advantages of the present invention will become more readily apparent to those of ordinary skill in the art after reviewing the following detailed description and accompanying drawings.

### BRIEF DESCRIPTION OF THE DRAWINGS

The structure and operation of the present invention will be understood from a review of the following detailed description and the accompanying drawings in which like reference numerals refer to like parts and in which:

FIG. 1 illustrates an embodiment of an apparatus used for detecting concealed explosives;

FIG. 2 illustrates an embodiment of an apparatus used for detecting concealed explosives;

FIG. 3A illustrates an embodiment of an apparatus used for detecting concealed explosives;

FIG. 3B illustrates an embodiment of an apparatus used for detecting concealed explosives;

FIGS. 4A-4C illustrate embodiments of a process for detecting concealed explosives; and

FIG. 5 illustrates a wired or wireless processor enabled device that may be used in connection with the various embodiments described herein.

### DETAILED DESCRIPTION

Certain embodiments disclosed herein provide for an apparatus and a method of detecting concealed explosives. For example, in various embodiments, a NQR scanner is used to detect the presence of explosives hidden inside electronic devices such as smartphones and tablet PCs. After reading this description it will become apparent to one skilled in the art how to implement the invention in various alternative embodiments and alternative applications. However, although various embodiments of the present invention will be described herein, it is understood that these embodiments are presented by way of example only, and not limitation. As such, this detailed description of various alternative embodiments should not be construed to limit the scope or breadth of the present invention as set forth in the appended claims.

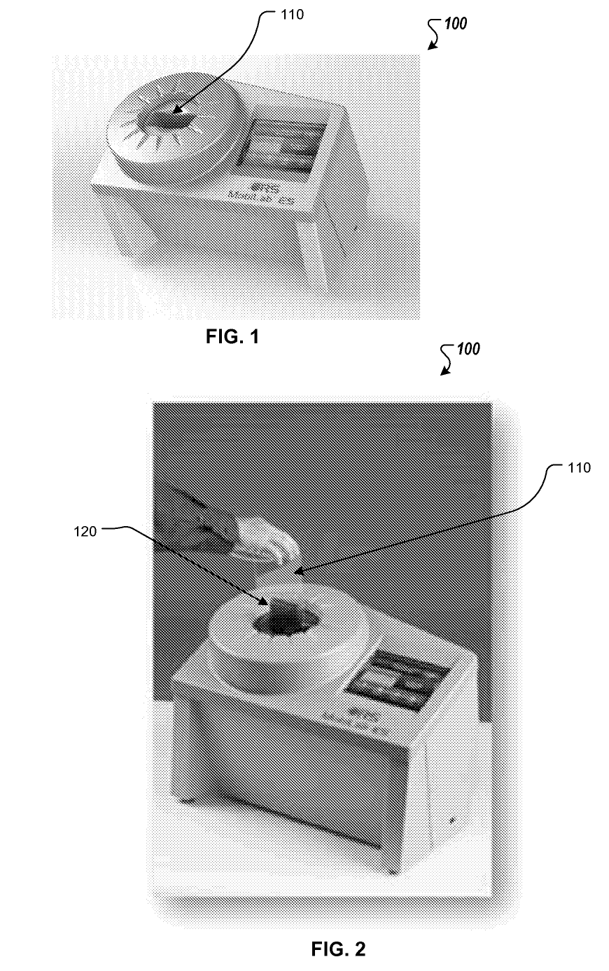

FIG. 1 illustrates an embodiment of Apparatus 100 used for detecting concealed explosives. In one exemplary embodiment, Apparatus 100 is a table top device that can be installed at a security checkpoint at an airport, a VIP event, or any other vulnerable area or facility. In various embodiments, Apparatus 100 comprises a NQR scanner. In various embodiments, Apparatus 100 includes an antenna (e.g., solenoid antenna) that generates interrogation electromagnetic radiation. In various embodiments, the interrogation electromagnetic radiation generated by the antenna are directed toward a target object such as an electronic device (e.g., smartphone, tablet PC). As described earlier, irradiating the target object with an interrogation electromagnetic radiation can cause the target object to emit feedback electromagnetic radiation. In various embodiments, the antenna is configured to generate a sequence of interrogation electromagnetic radiation at varying frequencies. Thus, in various embodiments, the target object is exposed to interrogation electromagnetic radiation at different frequencies. As described earlier, different chemical materials, compounds, or substances will absorb then emit electromagnetic radiation at individually unique NQR frequencies. The NQR frequency of a chemical material, compound, or substance thereby acts as a distinct chemical signature for that chemical material, compound, or substance. Thus, in various embodiments, Apparatus 100 is configured to irradiate the target object with interrogation electromagnetic radiation at frequencies corresponding to the NQR frequencies of the chemical components of one or more explosive materials, substances, or compounds, and to detect feedback electromagnetic radiation at those same frequencies. In various embodiments, Apparatus 100 further includes one or more sensors to detect, read, and/or measure the feedback electromagnetic radiation from the target object.

In various embodiments, Apparatus 100 is configured to identify potential explosive substances, materials, or compounds present in the target object based on the frequency of the feedback electromagnetic radiation. For instance, in various embodiments, the frequency of the feedback electromagnetic radiation from the target object is compared to or matched against the NQR frequencies associated with the various chemical components of one or more types of explosives. That is, since most explosive substances, materials, and compounds include a plurality of separate chemical components, in various embodiments, Apparatus 100 is configured to detect the presence of some or all of the chemical components in order to identity explosives that may have been hidden within the target object. For example, plastic Explosive X may contain Compound A as the primary explosive component, Compound B as a plasticizer, Compound C as a binder, and Compound D as the process oil. Thus, in one embodiment, to detect the presence of Explosive X, Apparatus 100 is configured to detect feedback electromagnetic radiation from the target object with a NQR frequency that uniquely identifies Compound A. In other embodiments, Apparatus 100 is configured to detect the presence of a predetermined and/or optimal number of chemical components that make up various explosive materials, compounds, or substances. It is to be understood that in various embodiments, Apparatus 100 is configured to perform separate and sequential tests or scans for each type of explosive material, compound, or substance. For example, Apparatus 100 is configured to detect different plastic explosives (e.g., Explosives X and Y) separately.

In some embodiments, the target device is irradiated with multiple rounds of interrogation electromagnetic radiation for each explosive in order to enhance the ratio of feedback electromagnetic radiation to any interference and/or noise signals. However, at least in some embodiments, Apparatus 100 is able interleave some or all of the detection process for different explosive compounds, materials, or substances, which optimizes the overall scan or detection time. For example, in some embodiments, Apparatus 100 is configured to intersperse multiple scans for Explosive X (e.g., irradiate the target object with interrogation electromagnetic radiation for Explosive X and detect feedback electromagnetic radiation) with one or more scans for Explosive Y.

In various embodiments, the overall detection time (i.e., NQR scan time) typically varies depending on the type(s) of explosive(s), since the nature of the NQR response is unique to each type of explosive material, substance, or compound. In some embodiments, the detection or scan time can be directly proportional to a total number of the different types of explosives that Apparatus 100 is required to detect. Furthermore, in various embodiments, both the overall scan or detection time and the confidence level associated with the detection results are directly proportional to the number of chemical components that Apparatus 100 is required to test with respect each explosive material, compound, or substance. In various embodiments, Apparatus 100 is generally able to complete one detection cycle or one full scan of a target object such as a smartphone or tablet PC within 2 to 10 seconds. Returning to the example with Explosives X and Y, in some embodiments, Apparatus 100 can additionally test for the presence of secondary components such as a plasticizer, binder, and/or process oil, in order to confirm or otherwise increase the certainty of the detection result. However, in some embodiments, Apparatus 100 can be configured to omit or bypass tests for certain chemical components, such as common or generic binders or plasticizers, in order to minimize the amount of time required to yield the detection result. In various embodiments, Apparatus 100 can be configured to test for an optimal number of chemical components depending on, for example, the compositions of the different explosive substances, materials, or compounds that Apparatus 100 is configured to detect for. Explosive Y, for example, is another type of plastic explosives and it contains the same explosive component, Compound A, as Explosive X. However, in addition to Compound A, Explosive Y also contains a different explosive component, Compound E. Thus, in some embodiments, in order to identify Explosive Y and to distinguish it from Explosive X, Apparatus 100 can be configured to test for Compound A and Compound B when detecting Explosive X, and to test for Compound A and Compound E when detecting Explosive Y.

In various embodiments, the amount of time the target object must be exposed to the interrogation electromagnetic radiation is inversely proportional to the size of the explosive material, compound, or substance. That is, in various embodiments, larger target objects require relatively shorter periods of irradiation before emitting sufficient feedback electromagnetic radiation to be read, measured, or detected by Apparatus 100. In various embodiments, Apparatus 100 is configured to irradiate the target object with a sequence of interrogation electromagnetic radiation at different or varying frequency. In certain exemplary embodiments, Apparatus 100 is configured to irradiate the target object with interrogation electromagnetic radiation for an optimal duration of time for each frequency in the sequence. In various embodiments, the optimal irradiation duration is determined based on an amount of irradiation time required to detect a certain minimum threat level (e.g., the least amount of explosives needed to cause harm or damage). In various embodiments, the optimal irradiation duration is further determined based on a Receiver Operational Characteristic (ROC) curve. In various embodiments, the ROC curve describes the relationship between the probability of detection and the false alarm rate.

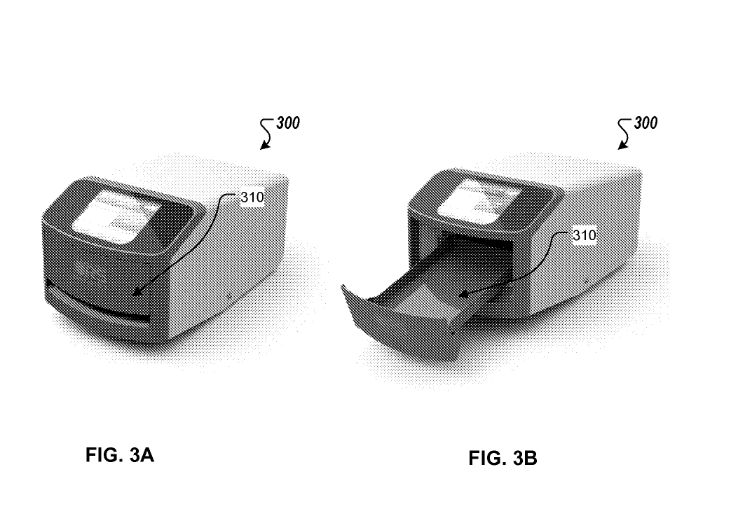

As shown in FIG. 1, Apparatus 100 includes a Detection Cavity 110. In various embodiments, the Detection Cavity 110 comprises an opening, a drawer, a conveyor system, or any other appropriate receptacle, medium, and/or mechanism to hold, enclose, or otherwise contain the target object. In various embodiments, Apparatus 100 irradiates the target object inserted or placed in Detection Cavity 110 with interrogation electromagnetic radiation at varying frequencies. Furthermore, in various embodiments, Apparatus 100 comprises sensors that detect, read and/or measure feedback electromagnetic radiation from the target object inserted or placed in Detection Cavity 110. In certain exemplary embodiments, Detection Cavity 110 is configured to orient the target object in a position that minimizes the profile of the target object or its angle with respect to the antenna and to the interrogation electromagnetic radiation. In particular, where the target object is an electronic device such as a smartphone or tablet PC, conductive surfaces tend to be aligned with the exterior surface of the electronic device. Thus, in various embodiments where the target object is positioned substantially parallel to the antenna, its conductive surfaces also remain substantially parallel to the interrogation electromagnetic radiation generated by the antenna. FIG. 2 depicts a Target Object 120, a smartphone in this case, being inserted into Detection Cavity 110 of Apparatus 100 in the manner described (i.e., substantially parallel to the antenna). In some embodiments, Target Object 120 is oriented in at less than a 20-degree angle relative to the antenna and to the interrogation electromagnetic radiation. In various embodiments, positioning the conductive surfaces substantially parallel (e.g., less than 20 degrees) to the interrogation electromagnetic radiation avoids or minimizes electric currents that can be induced across the conductive surfaces by orthogonally directed electromagnetic radiation. Advantageously, eliminating induced currents will generally also eliminate the concomitant noise signals, which can mask the actual feedback electromagnetic radiation from explosives hidden within Target Object 120.

In various exemplary embodiments, Apparatus 100 is configured to detect explosives that have been concealed within an electronic device such as a smartphone or a tablet PC. In some embodiments, Apparatus 100 is configured to operate (i.e., perform NQR scans) on the electronic device when the electronic device has been powered off. When powered on, an electronic device such as a smartphone or tablet PC tends to generate undesirable noise signals that mask or otherwise interfere with the feedback electromagnetic radiation from explosives potentially hidden within the electronic device. Noise and other types of interference signals described in more detail below generally compromises the accuracy and reliability of scans performed by Apparatus 100 (e.g., increased rates of false positives and/or false negatives). However, in certain situations, it may be desirable, necessary, and/or appropriate to test an electronic device without having to power the device off first. Thus, in some embodiments, Apparatus 100 is configured to suppress signals that can come from an electronic device that is left on during the NQR scanning process. Alternately or in addition, in various embodiments, Apparatus 100 is configured to detect the feedback electromagnetic radiation within the noise signals generated by the electronic device.

In various embodiments, Apparatus 100 is additionally configured to measure the level of interference signals. For example, in some instances, Apparatus 100 may be subject to intentional jamming signals and/or interference signals from the surrounding environment. In certain exemplary embodiments, Apparatus 100 is configured to generate audio and/or visual alarms or alerts when it detects an unusual (e.g., greater than a certain threshold) level of interference signals. For example, in some embodiments, Apparatus 100 can indicate via a visual and/or audio output that an accurate or reliable scan cannot be performed as a result of interference signals.

As described earlier, some explosive substances, materials, or compounds (e.g., Explosives X and Y) comprise multiple chemical components. As such, some explosive substances feature feedback electromagnetic radiation at multiple resonant frequencies. Thus, in some embodiments, Apparatus 100 can be configured to irradiate the target object with additional frequencies of interrogation electromagnetic radiation in the event that Apparatus 100 detects excessive level(s) (e.g., greater than predetermined threshold) of noise and/or interference signals. For example, in one embodiment, Apparatus 100 can be configured to test the target object for Compound A of Explosive X. Suppose that Apparatus 100 detects an excessive amount of concomitant noise and/or interference signals. Under such circumstances, in some embodiments, Apparatus 100 can additionally test the target object for Compound B, C, and/or D of Explosive X in order to enhance the accuracy or confidence level associated with the detection results.

Although not shown in FIG. 1, in certain exemplary embodiments, Apparatus 100 can further comprise one or more shielding mechanisms to block interference signals from the surrounding environment. In various embodiments, some or all components of Apparatus 100 can be isolated from external interference signals using passive shielding. For example, in some embodiments, Detection Cavity 110 can be enclosed in conductive material (e.g., a Faraday Cage). Alternately, in some embodiments, Detection Cavity 110 can comprise a shielded “can” or “quiet tunnel” with an open top. The dimensions (i.e., length, width, and height) of the can or tunnel affect the propagation of interference signals on the inside of the can or tunnel. As such, in various embodiments, Apparatus 100 includes a shielded can or quiet tunnel with dimensions that optimize the deterrence or suppression of interference signals from the surrounding environment.

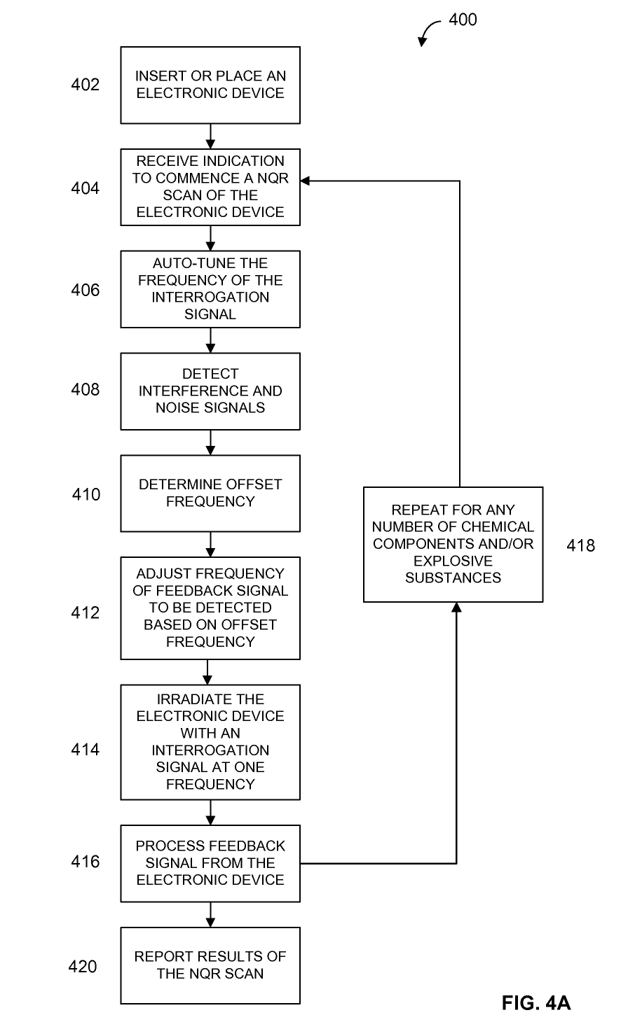

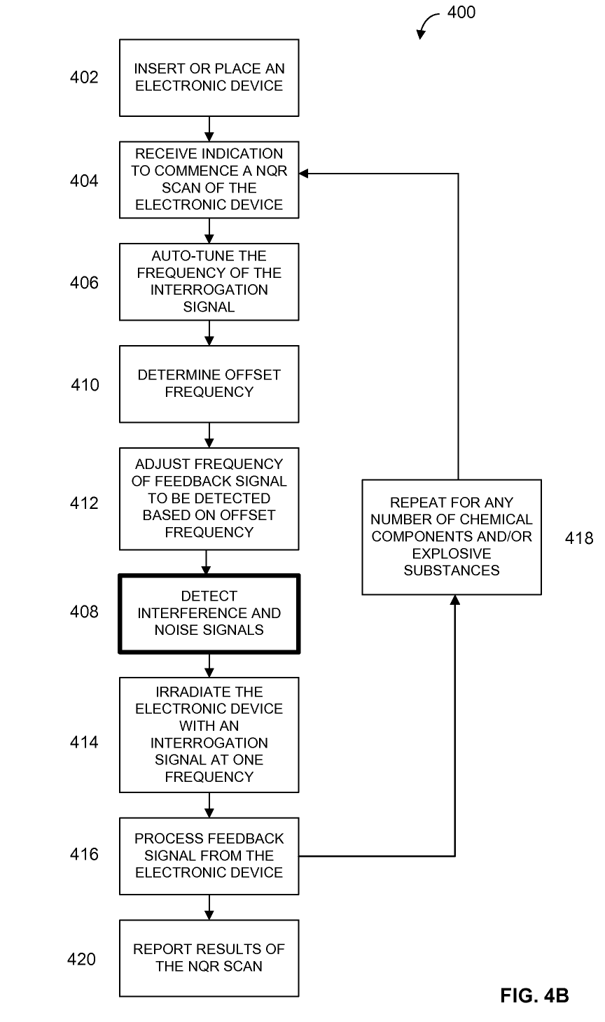

FIG. 3A and FIG. 3B illustrates an embodiment of Apparatus 300 used for detecting concealed explosives. In various embodiments, Apparatus 300 is similar to Apparatus 100 described with respect to FIG. 1. However, in various embodiments, Apparatus 300 provides a different type or form of detection cavity. As depicted in FIG. 3A and 3B, Apparatus 300 includes Detection Cavity 310, which is shown as a drawer. In various embodiments, a target object is placed inside the drawer (i.e., Detection Cavity 310), which can then be slide shut. FIG. 3A shows Apparatus 300 with Detection Cavity 310 in a shut position while FIG. 3B shows Apparatus 300 with Detection Cavity 310 in an open and pulled out position.

Alternately, instead of the drawer depicted in FIG. 3A and 3B, in other embodiments, Detection Cavity 310 can comprise a pass through tray and/or a conveyor system. In those embodiments, the sensors in Apparatus 300 are positioned or spaced based on the timing of the target object's passage through Detection Cavity 310. That is, in various embodiments, the sensors to detect, read, or measure feedback electromagnetic radiation from the target object are positioned a sufficient distance from the antenna generating the interrogation electromagnetic radiation such that the target object can be irradiated for an adequate length of time before the sensors attempts to detect, read, or measure the feedback electromagnetic radiation.

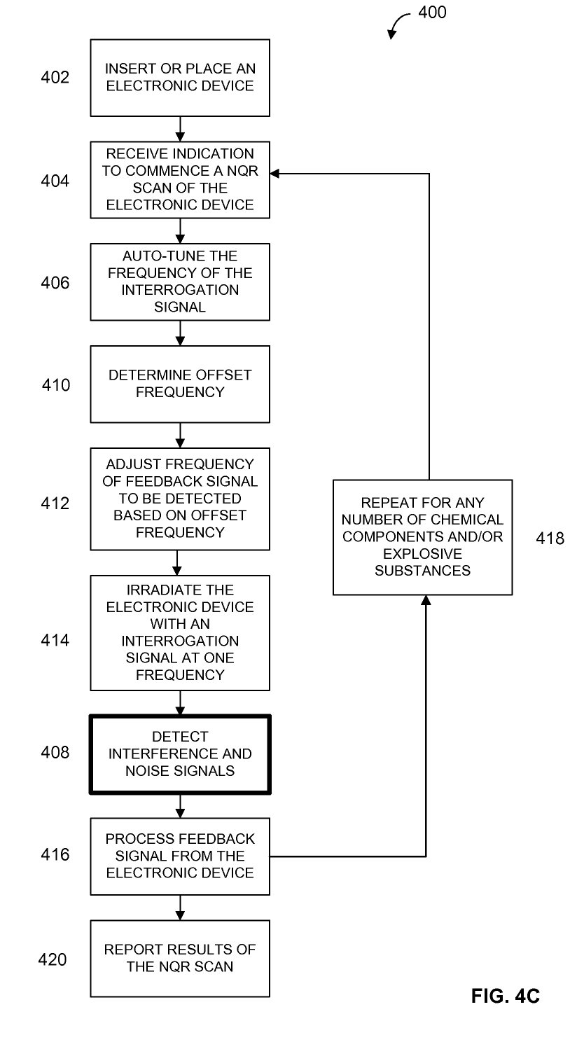

FIG. 4A illustrates an embodiment of a Process 400 for detecting explosives concealed within an electronic device. In various embodiments, Process 400 can be performed using Apparatus 100 described with respect to FIG. 1, or Apparatus 300 described with respect to FIG. 3A and 3B. At 402, the electronic device is inserted or placed in the detection cavity of the apparatus. At 404, an indication is received to commence the NQR scan. For example, in some embodiments, an operator (e.g., a TSA agent) can press an “INSPECT” or “SCAN” button on the apparatus. As another example, in some embodiments, the apparatus can provide a touch screen, in which case the NQR scan can be initiated using one or more graphic user interface (GUI) control components displayed on the touch screen. Alternately, in some embodiments, the NQR scan is triggered by the insertion or placement of the electronic device inside the detection cavity. As such, in various embodiments, the NQR scan can be initiated with or without explicit manual input. At 406, the apparatus auto-tunes the frequency of the interrogation electromagnetic radiation. In various embodiments, the interrogation electromagnetic radiation is auto-tuned to the NQR frequency that corresponds to a chemical component of a certain explosive material, substance, or compound (e.g., Compound A, B, C, or D in Explosive X). In various embodiments, the apparatus is configured to expose the electronic device to a sequence of interrogation electromagnetic radiation at different frequencies, corresponding to different chemical components and/or explosives. As such, in various embodiments, the apparatus auto-tunes such that the antenna generates interrogation electromagnetic radiation at the appropriate frequencies.

At 408, interference and noise signals are detected. In various embodiments, interference and noise signals can originate from a variety of sources, including but not limited to the environment, the electronic device itself, and intentional jamming. At 410, an offset frequency is determined. In various embodiments, the offset frequency is determined based at least in part on the interference and noise signals detected at 408. For example, in some embodiments, the offset frequency accounts for the noise signals generated by the presence of the electronic device. In particular, in the event that the electronic device is to remain powered on during the NQR scan, the electronic device can generate undesirable noise signals that mask or otherwise interfere with feedback electromagnetic radiation from explosive materials. At 412, the frequency of the feedback electromagnetic radiation that the apparatus is configured to detect is adjusted based on the offset frequency. At 414, the electronic device is irradiated with interrogation electromagnetic radiation at a frequency that is specific to a particular chemical component. In various embodiments, the chemical component is one of a plurality of chemical components comprising an explosive material, substance, or compound. As such, in some embodiments, presence of one or all of the chemical components of an explosive can indicate the presence of the explosive within the target object. At 416, the feedback electromagnetic radiation is measured and processed. In various embodiments, processing includes but is not limited to noise suppression, filtering, signal addition, and elimination of signal bursts. At 418, steps 404-416 are repeated for a desired, required, or appropriate number of chemical components and/or explosive substances, materials, or compounds. Finally, at 420, the results of the NQR scan are reported. For example, in some embodiments, the apparatus can provide an audio and/or visual alarm indicating that an explosive material, substance, or compound has been detected within the electronic device. In addition, in various embodiments, the apparatus is able to indicate, such as via the touch screen, the type(s) of explosive(s) detected.

Although Process 400 illustrated in FIG. 4A is described to include steps 402-420, a person of ordinary skill in the art can appreciate that some steps, such as step 404, can be fully or partially omitted. Furthermore, other than the sequence or order shown in FIG. 4A, it is to be understood that steps 402-420 of Process 400 can be performed in any appropriate order or sequence.

For example, in FIG. 4B, step 408 for detecting interference signals and noise signals takes place between steps 412 and 414. In the embodiment shown in FIG. 4B, the offset frequency is not determined based at least in part on the interference and noise signals detected in step 408.

Similarly, in FIG. 4C, step 408 for detecting interference signals and noise signals takes place between steps 414 and 416. Additionally, in the embodiment shown in FIG. 4C, the offset frequency is not determined based at least in part on the interference and noise signals detected in step 408.

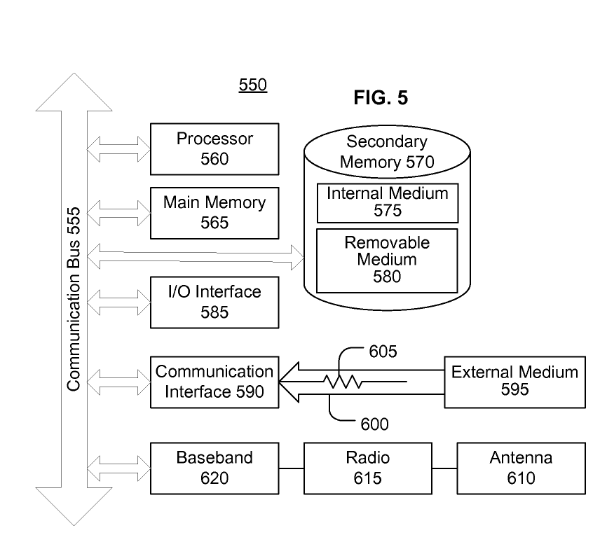

FIG. 5 is a block diagram illustrating an embodiment of a wired or wireless System 550 that may be used in connection with various embodiments described herein. For example the System 550 may be used to implement various controller modules comprising Apparatus 100 described with respect to FIG. 1. The system 550 can be a conventional personal computer, computer server, personal digital assistant, smart phone, tablet computer, or any other processor enabled device that is capable of wired or wireless data communication. Other computer systems and/or architectures may be also used, as will be clear to those skilled in the art.

System 550 preferably includes one or more processors, such as processor 560. Additional processors may be provided, such as an auxiliary processor to manage input/output, an auxiliary processor to perform floating point mathematical operations, a special-purpose microprocessor having an architecture suitable for fast execution of signal processing algorithms (e.g., digital signal processor), a slave processor subordinate to the main processing system (e.g., back-end processor), an additional microprocessor or controller for dual or multiple processor systems, or a coprocessor. Such auxiliary processors may be discrete processors or may be integrated with the processor 560.

The processor 560 is preferably connected to a communication bus 555. The communication bus 555 may include a data channel for facilitating information transfer between storage and other peripheral components of the system 550. The communication bus 555 further may provide a set of signals used for communication with the processor 560, including a data bus, address bus, and control bus (not shown). The communication bus 555 may comprise any standard or non-standard bus architecture such as, for example, bus architectures compliant with industry standard architecture (“ISA”), extended industry standard architecture (“EISA”), Micro Channel Architecture (“MCA”), peripheral component interconnect (“PCI”) local bus, or standards promulgated by the Institute of Electrical and Electronics Engineers (“IEEE”) including IEEE 488 general-purpose interface bus (“GPIB”), IEEE 696/S-100, and the like.

System 550 preferably includes a main memory 565 and may also include a secondary memory 570. The main memory 565 provides storage of instructions and data for programs executing on the processor 560. The main memory 565 is typically semiconductor-based memory such as dynamic random access memory (“DRAM”) and/or static random access memory (“SRAM”). Other semiconductor-based memory types include, for example, synchronous dynamic random access memory (“SDRAM”), Rambus dynamic random access memory (“RDRAM”), ferroelectric random access memory (“FRAM”), and the like, including read only memory (“ROM”).

The secondary memory 570 may optionally include a internal memory 575 and/or a removable medium 580, for example a floppy disk drive, a magnetic tape drive, a compact disc (“CD”) drive, a digital versatile disc (“DVD”) drive, etc. The removable medium 580 is read from and/or written to in a well-known manner. Removable storage medium 580 may be, for example, a floppy disk, magnetic tape, CD, DVD, SD card, etc.

The removable storage medium 580 is a non-transitory computer readable medium having stored thereon computer executable code (i.e., software) and/or data. The computer software or data stored on the removable storage medium 580 is read into the system 550 for execution by the processor 560.

In alternative embodiments, secondary memory 570 may include other similar means for allowing computer programs or other data or instructions to be loaded into the system 550. Such means may include, for example, an external storage medium 595 and an interface 570. Examples of external storage medium 595 may include an external hard disk drive or an external optical drive, or and external magneto-optical drive.

Other examples of secondary memory 570 may include semiconductor-based memory such as programmable read-only memory (“PROM”), erasable programmable read-only memory (“EPROM”), electrically erasable read-only memory (“EEPROM”), or flash memory (block oriented memory similar to EEPROM). Also included are any other removable storage media 580 and communication interface 590, which allow software and data to be transferred from an external medium 595 to the system 550.

System 550 may also include an input/output (“I/O”) interface 585. The I/O interface 585 facilitates input from and output to external devices. For example the I/O interface 585 may receive input from a keyboard or mouse and may provide output to a display. The I/O interface 585 is capable of facilitating input from and output to various alternative types of human interface and machine interface devices alike.

System 550 may also include a communication interface 590. The communication interface 590 allows software and data to be transferred between system 550 and external devices (e.g. printers), networks, or information sources. For example, computer software or executable code may be transferred to system 550 from a network server via communication interface 590. Examples of communication interface 590 include a modem, a network interface card (“NIC”), a wireless data card, a communications port, a PCMCIA slot and card, an infrared interface, and an IEEE 1394 fire-wire, just to name a few.

Communication interface 590 preferably implements industry promulgated protocol standards, such as Ethernet IEEE 802 standards, Fiber Channel, digital subscriber line (“DSL”), asynchronous digital subscriber line (“ADSL”), frame relay, asynchronous transfer mode (“ATM”), integrated digital services network (“ISDN”), personal communications services (“PCS”), transmission control protocol/Internet protocol (“TCP/IP”), serial line Internet protocol/point to point protocol (“SLIP/PPP”), and so on, but may also implement customized or non-standard interface protocols as well.

Software and data transferred via communication interface 590 are generally in the form of electrical communication signals 605. These signals 605 are preferably provided to communication interface 590 via a communication channel 600. In one embodiment, the communication channel 600 may be a wired or wireless network, or any variety of other communication links. Communication channel 600 carries signals 605 and can be implemented using a variety of wired or wireless communication means including wire or cable, fiber optics, conventional phone line, cellular phone link, wireless data communication link, radio frequency (“RF”) link, or infrared link, just to name a few.

Computer executable code (i.e., computer programs or software) is stored in the main memory 565 and/or the secondary memory 570. Computer programs can also be received via communication interface 590 and stored in the main memory 565 and/or the secondary memory 570. Such computer programs, when executed, enable the system 550 to perform the various functions of the present invention as previously described.

In this description, the term “computer readable medium” is used to refer to any non-transitory computer readable storage media used to provide computer executable code (e.g., software and computer programs) to the system 550. Examples of these media include main memory 565, secondary memory 570 (including internal memory 575, removable medium 580, and external storage medium 595), and any peripheral device communicatively coupled with communication interface 590 (including a network information server or other network device). These non-transitory computer readable mediums are means for providing executable code, programming instructions, and software to the system 550.

In an embodiment that is implemented using software, the software may be stored on a computer readable medium and loaded into the system 550 by way of removable medium 580, I/O interface 585, or communication interface 590. In such an embodiment, the software is loaded into the system 550 in the form of electrical communication signals 605. The software, when executed by the processor 560, preferably causes the processor 560 to perform the inventive features and functions previously described herein.

The system 550 also includes optional wireless communication components that facilitate wireless communication over a voice and over a data network. The wireless communication components comprise an antenna system 610, a radio system 615 and a baseband system 620. In the system 550, radio frequency (“RF”) signals are transmitted and received over the air by the antenna system 610 under the management of the radio system 615.

In one embodiment, the antenna system 610 may comprise one or more antennae and one or more multiplexors (not shown) that perform a switching function to provide the antenna system 610 with transmit and receive signal paths. In the receive path, received RF signals can be coupled from a multiplexor to a low noise amplifier (not shown) that amplifies the received RF signal and sends the amplified signal to the radio system 615.

In alternative embodiments, the radio system 615 may comprise one or more radios that are configured to communicate over various frequencies. In one embodiment, the radio system 615 may combine a demodulator (not shown) and modulator (not shown) in one integrated circuit (“IC”). The demodulator and modulator can also be separate components. In the incoming path, the demodulator strips away the RF carrier signal leaving a baseband receive audio signal, which is sent from the radio system 615 to the baseband system 620.

If the received signal contains audio information, then baseband system 620 decodes the signal and converts it to an analog signal. Then the signal is amplified and sent to a speaker. The baseband system 620 also receives analog audio signals from a microphone. These analog audio signals are converted to digital signals and encoded by the baseband system 620. The baseband system 620 also codes the digital signals for transmission and generates a baseband transmit audio signal that is routed to the modulator portion of the radio system 615. The modulator mixes the baseband transmit audio signal with an RF carrier signal generating an RF transmit signal that is routed to the antenna system and may pass through a power amplifier (not shown). The power amplifier amplifies the RF transmit signal and routes it to the antenna system 610 where the signal is switched to the antenna port for transmission.

The baseband system 620 is also communicatively coupled with the processor 560. The central processing unit 560 has access to data storage areas 565 and 570. The central processing unit 560 is preferably configured to execute instructions (i.e., computer programs or software) that can be stored in the memory 565 or the secondary memory 570. Computer programs can also be received from the baseband processor 610 and stored in the data storage area 565 or in secondary memory 570, or executed upon receipt. Such computer programs, when executed, enable the system 550 to perform the various functions of the present invention as previously described. For example, data storage areas 565 may include various software modules (not shown) that are executable by processor 560.

Various embodiments may also be implemented primarily in hardware using, for example, components such as application specific integrated circuits (“ASICs”), or field programmable gate arrays (“FPGAs”). Implementation of a hardware state machine capable of performing the functions described herein will also be apparent to those skilled in the relevant art. Various embodiments may also be implemented using a combination of both hardware and software.

Furthermore, those of skill in the art will appreciate that the various illustrative logical blocks, modules, circuits, and method steps described in connection with the above described figures and the embodiments disclosed herein can often be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled persons can implement the described functionality in varying ways for each particular application, but such implementation decisions should not be interpreted as causing a departure from the scope of the invention. In addition, the grouping of functions within a module, block, circuit or step is for ease of description. Specific functions or steps can be moved from one module, block or circuit to another without departing from the invention.

Moreover, the various illustrative logical blocks, modules, and methods described in connection with the embodiments disclosed herein can be implemented or performed with a general purpose processor, a digital signal processor (“DSP”), an ASIC, FPGA or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

Additionally, the steps of a method or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium including a network storage medium. An exemplary storage medium can be coupled to the processor such the processor can read information from, and write information to, the storage medium. In the alternative, the storage medium can be integral to the processor. The processor and the storage medium can also reside in an ASIC.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly not limited.

1. An apparatus, comprising:
an antenna module configured to generate interrogation electromagnetic radiation at a first frequency;
a detection cavity configured to receive an electronic device, wherein the electronic device inside the detection cavity is irradiated for a predetermined period of time with the interrogation electromagnetic radiation at the first frequency;
a sensor module configured to measure feedback electromagnetic radiation emitted by the electronic device in response to the interrogation electromagnetic radiation at the first frequency; and
a user interface module configured to present, on a display, an indication generated based at least in part on an analysis of the feedback electromagnetic radiation emitted by the electronic device in response to the interrogation electromagnetic radiation at the first frequency.

2. (canceled)

3. The apparatus of claim 1, wherein the detection cavity comprises one of an opening, a drawer, a shielded can or a quiet tunnel and wherein one or more dimensions of the detection cavity is optimized based at least in part on a suppression of external signals.

4. (canceled)

5. (canceled)

6. The apparatus of claim 1, wherein the detection cavity comprises a conveyor system or a pass through tray and one or more sensors of the sensor module are positioned to detect the feedback electromagnetic radiation while the target object is in motion on the conveyor system or the pass through tray.

7. The apparatus of claim 1, wherein the predetermined period of time is determined based at least in part on one of the following: a minimum size or amount of explosives to be detected, and a receiver operational characteristic (ROC) curve.

8. (canceled)

9. The apparatus of claim 1, further comprising an interference module configured to measure a level of interference and noise signals from at least one of the following: the electronic device inside the detection cavity and the environment surrounding the apparatus.

10. The apparatus of claim 1, wherein the detection cavity is configured to orient the electronic device in order to minimize a profile of the electronic device with respect to the antenna module, and wherein the electronic device inside the detection device remains substantially parallel to the interrogation electromagnetic radiation.

11. The apparatus of claim 9, wherein the feedback electromagnetic radiation emitted by the electronic device in response to the interrogation electromagnetic radiation at the first frequency is analyzed at least in part by adjusting the feedback electromagnetic radiation based on the level of interference and noise signals, and by comparing a frequency of the feedback electromagnetic radiation with the first frequency.

12. The apparatus of claim 1, wherein the first frequency corresponds to the NQR frequency of a first chemical component comprising a first explosive compound, wherein the antenna module is further configured to generate interrogation electromagnetic radiation at a second frequency, and wherein the target object inside the detection cavity is irradiated for the predetermined period of time with the interrogation electromagnetic radiation at the second frequency.

13. The apparatus of claim 12, wherein the second frequency corresponds to a NQR frequency of a second chemical component comprising one of the following: the first explosive compound, and a second explosive compound.

14. The apparatus of claim 12, wherein the sensor module is further configured to measure feedback electromagnetic radiation emitted by the electronic device in response to the interrogation electromagnetic radiation at the second frequency, and wherein the indication output by the user interface module is further generated based at least in part on an analysis of the feedback electromagnetic radiation emitted by the electronic device in response to the interrogation electromagnetic radiation at the second frequency.

15. The apparatus of claim 12, wherein the antenna module is configured to generate interrogation electromagnetic radiation at the second frequency in the event that a level of one or more noise or interference signals is determined to exceed a predetermined threshold.

16. A method, comprising:
generating, using an antenna module, interrogation electromagnetic radiation at a first frequency;
irradiating, for a predetermined period of time, an electronic device inside a detection cavity with the interrogation electromagnetic radiation at the first frequency;
measuring, using a sensor module, feedback electromagnetic radiation emitted by the electronic device in response to the interrogation electromagnetic radiation at the first frequency;
analyzing the feedback electromagnetic radiation emitted by the electronic device in response to the interrogation electromagnetic radiation at the first frequency; and
presenting, on a display, an indication generated based at least in part on the analysis of the feedback electromagnetic radiation emitted by the electronic device in response to the interrogation electromagnetic radiation at the first frequency.

17. The method of claim 16, wherein one or more sensors of the sensor module are positioned to detect the feedback electromagnetic radiation while the target object is in motion on a conveyor system.

18. The method of claim 16, wherein the detection cavity is configured to orient the electronic device in order to minimize a profile of the electronic device with respect to the antenna module, and wherein the electronic device inside the detection device remains substantially parallel to the interrogation electromagnetic radiation.

19. The method of claim 16, wherein the predetermined period of time is determined based at least in part on one of the following: a minimum size or amount of explosives to be detected, and a receiver operational characteristic (ROC) curve.

20. (canceled)

21. The method of claim 16, further comprising measuring a level of interference and noise signals from at least one of the following: the electronic device inside the detection cavity, and the environment surrounding the apparatus.

22. The method of claim 21, wherein the feedback electromagnetic radiation emitted by the electronic device in response to the interrogation electromagnetic radiation at the first frequency is analyzed at least in part by adjusting the feedback electromagnetic radiation based on the level of interference and noise signals, and by comparing a frequency of the feedback electromagnetic radiation with the first frequency.

23. The method of claim 16,
wherein the first frequency corresponds to the NQR frequency of a first chemical component comprising a first explosive compound,
wherein the antenna module is further configured to generate interrogation electromagnetic radiation at a second frequency that corresponds to a NQR frequency of a second chemical component comprising one of the following: the first explosive compound, and a second explosive compound,
wherein the target object inside the detection cavity is irradiated for the predetermined period of time with the interrogation electromagnetic radiation at the second frequency.

24. (canceled)

25. The method of claim 23, wherein sensors module is further configured to measure feedback electromagnetic radiation emitted by the electronic device in response to the interrogation electromagnetic radiation at the second frequency, and wherein the indication output by the user interface module is further generated based at least in part on an analysis of the feedback electromagnetic radiation emitted by the electronic device in response to the interrogation electromagnetic radiation at the second frequency.

26. The method of claim 23, wherein the antenna module is configured to generate interrogation electromagnetic radiation at the second frequency in the event that a level of one or more noise or interference signals is determined to exceed a predetermined threshold.
